(19) United States
(12) Patent Application Publication
(10) Pub. No.: US 2014/0035073 A1
(43) Pub. Date: Feb. 6, 2014

(54) MAGNETO-RESISTIVE ELEMENT

(71) Applicant: KABUSHIKI KAISHA TOSHIBA, Tokyo (JP)

(72) Inventors: Masaru TOKO, Kanagawa (JP); Tatsuya Kishi, Kanagawa (JP); Masahiko Nakayama, Yamaguchi (JP); Hiroaki Yoda, Kanagawa (JP)

(73) Assignee: Kabushiki Kaisha Toshiba, Tokyo (JP)

(21) Appl. No.: 13/777,694

(22) Filed: Feb. 26, 2013

(30) Foreign Application Priority Data
Aug. 3, 2012 (JP) 2012-172771

(51) Int. Cl. H01L 43/02

(52) U.S. Cl. CPC H01L 43/02
USPC 257/421

(57) ABSTRACT

A magneto-resistive element has a memory layer, which has magnetic anisotropy along a direction perpendicular to its surface and variable magnetization directions, a reference layer, which has magnetic anisotropy along a direction perpendicular to its surface and a fixed magnetization direction, and a tunnel barrier layer, which is formed between the memory layer and the reference layer. The memory layer is composed of Co₁₋ₓFeₓB, where 0.4≦x<0.6 and the thickness is 0.7 nm or more but less than 1.0 nm; or where 0.6≦x<0.8 and the thickness is 0.7 nm or more but less than 1.1 nm; or where 0.8≦x<1.0 and the thickness is 0.9 nm or more but less than 1.2 nm.

### CROSS-REFERENCE TO RELATED APPLICATION

This application is based upon and claims the benefit of priority from Japanese Patent Application No. 2012-172771, filed Aug. 3, 2012; the entire contents of which are incorporated herein by reference.

### FIELD

Embodiments described herein relate a magneto-resistive element.

### BACKGROUND

Magnetic Random Access Memory (MRAM) of a spin-injection type, which includes a memory element with a magneto-resistive element containing magnetic layers, has been developed. In order to store information in the MRAM, the electric resistance of the magneto-resistive element is controlled to either a high-resistant state or a low-resistant state by changing the magnetization direction of the magnetic layers, using the electric current injected into the magneto-resistive element.

It is important for the spin-injection type MRAM to reduce the current (e.g., writing current), that inverts the magnetization direction of the magnetic layers during the memory operation. On the other hand, it is necessary to increase the inversion energy barrier between P-state (parallel state, where the direction of magnetization of the storage layer and the reference layer is parallel) and AP-state (anti-parallel state, where the direction of magnetization of the storage layer and the reference layer is not parallel) in order to retain data written as a non-volatile memory. Reducing the inversion current and increasing the inversion energy barrier, however, conflict with each other, and it is difficult to reconcile the two.

### DESCRIPTION OF THE DRAWINGS

FIG. 1 is a circuit diagram showing a single memory cell of an MRAM.

FIG. 2 is a cross-sectional view showing the configuration of the MRAM memory cell.

FIG. 3 is a cross-sectional view showing the configuration of a magneto-resistive element according to an embodiment.

FIG. 4 is a graph showing the relationship between magnetic properties of a memory layer and its thickness.

FIG. 5 is a graph showing the relationship between the thickness of the memory layer and inversion current.

FIG. 6 is a graph showing the relationship between the thickness of the memory layer and inversion energy barrier.

FIG. 7 is a graph showing the relationship between the thickness of the memory layer and the ratio of the inversion current to the inversion energy barrier.

FIG. 8 is a graph showing the relationship between the thickness of the memory layer and a magnetic property of the memory layer for different composition ratios of Fe in the memory layer.

### DETAILED DESCRIPTION

The purpose of this embodiment is to provide a magneto-resistive element that reduces the writing current, while suppressing the deterioration of data retention property.

In general, embodiments will be explained below referring to the drawings. In the drawings, the same parts are denoted with the same reference numbers. Also, there will be overlapping explanations as needed.

The magneto-resistive element according to an embodiment has a memory layer, which has magnetic anisotropy along a direction perpendicular to its surface and variable magnetization directions; a reference layer, which has a magnetic anisotropy along a direction perpendicular to its surface and a fixed magnetization direction; and a tunnel barrier layer, which is formed between the memory layer and the reference layer. The memory layer is composed of Co₁₋ₓFeₓB, where 0.4≦x<0.6 and the thickness is 0.7 nm or more but less than 1.0 nm; or where 0.6≦x<0.8 and the thickness is 0.7 nm or more but less than 1.1 nm; or where 0.8≦x<1.0 and the thickness is 0.9 nm or more but less than 1.2 nm.

### (MRAM Construction Examples)

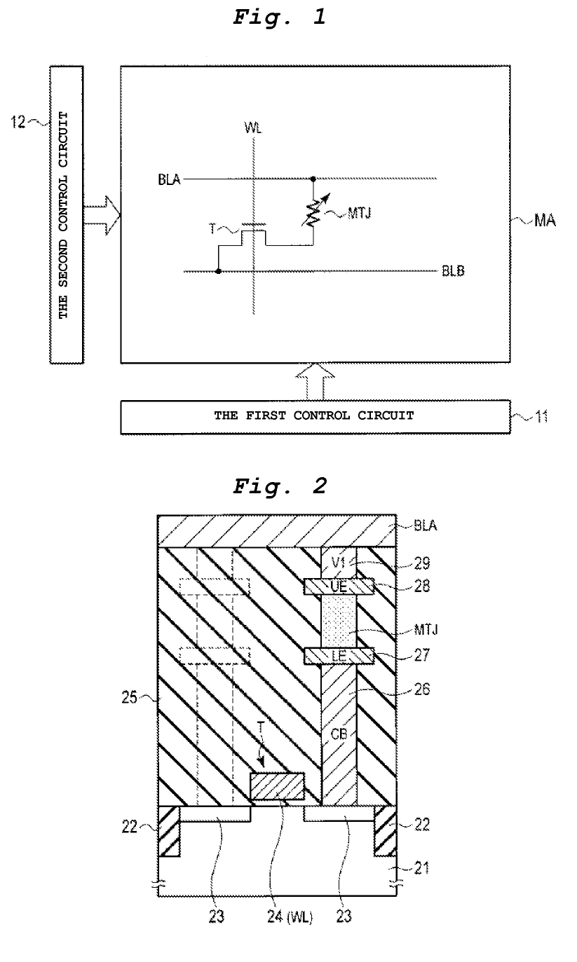

The construction examples of MRAM will be explained using FIG. 1 and FIG. 2.

FIG. 1 is a circuit diagram showing the memory cell of MRAM.

As shown in FIG. 1, the memory cell in memory cell array MA has a series connection between magneto-resistive element MTJ and switch element (for example FET) T. One end of the series connection (one end of magneto-resistive element MTJ) is connected to bit line BLA, and the other end of the series connection (one end of switch element T) is connected to bit line BLB. A control element of switch element T, for example, a gate electrode of FET, is connected to word line WL.

The potential of word line WL is controlled by the first control circuit 11. Also, the potential of bit lines BLA and BLB is controlled by the second control circuit 12.

FIG. 2 is a cross-sectional view showing the construction of the memory cell of MRAM.

As shown in FIG. 2, the memory includes a switch element T, which is positioned on the semiconductor substrate 21 and the magneto-resistive element MTJ.

The semiconductor substrate 21, for example, is a silicon substrate, and its conductivity type can be either P-type or N-type. In the semiconductor substrate 21, SiO₂ (silicon dioxide) with the STI structure is arranged as one example of an element isolation insulating layer 22.

In the surface area of the semiconductor substrate 21, in particular the element area (active area) surrounded by element isolation insulating layer 22, a switch element T is arranged. In this example, the switch element T is FET, and has two source/drain diffusion layers 23 within the semiconductor substrate 21, and a gate electrode 24, which is positioned on the channel area between the these layers. The gate electrode 24 functions as a word line WL.

The switch element T is covered with an inter-layer insulation layer (for example, SiO₂) 25. A contact hole is formed within the inter-layer isolation layer 25. A contact via (CB) 26 is arranged inside a contact hole. The contact via (CB) 26, for example, is composed of such metallic materials as W and Cu.

The bottom surface of the contact via 26 is connected to the switch element. In this example, the contact via 26 has a direct contact with a source/drain diffusion layer 23.

On contact via 26, a lower electrode (LE) 27 is arranged. The lower electrode 27 has a layered structure of, for example, Ta (10 nm)/Ru (5 nm)/Ta (5 nm).

On lower electrode 27, namely, directly above the contact via 26, a magneto-resistive element MTJ is arranged. A detailed explanation of the magneto-resistive element MTJ of this embodiment will be provided later.

On the magneto-resistive element MTJ, an upper electrode (UE) 28 is arranged. The upper electrode 28, for example, is composed of TiN. The upper electrode 28 is connected to bit line (for example, Cu) BLA, through a via (for example Cu) 29.

### Embodiment

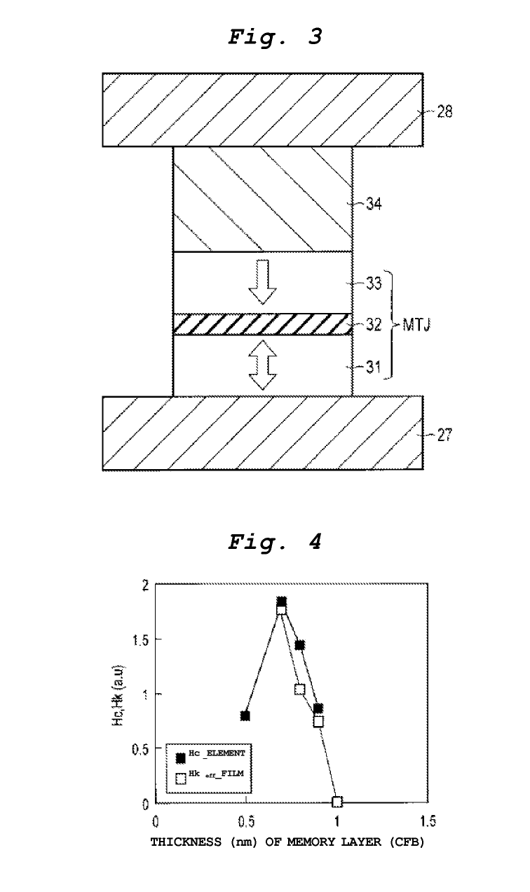

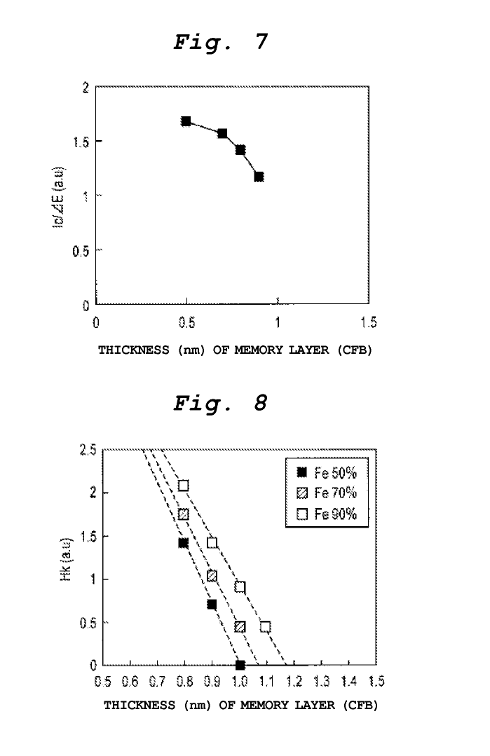

The magneto-resistive element MTJ of this embodiment will be explained using FIG. 3 and FIG. 8. In this embodiment, inverse current Ic is reduced while inverse energy barrier ΔE is kept at a high level, by adjusting the thickness of the memory layer 31 and the composition ratio of Fe. By this, it is possible to reduce the writing current, while suppressing the deterioration of the data retention property. A detailed explanation of magneto-resistive element MTJ of this embodiment is provided below.

### (Configuration)

First, the construction of magneto-resistive element MTJ of this embodiment will be explained using FIG. 3.

FIG. 3 is a cross-sectional view showing the construction of the magneto-resistive element MTJ of this embodiment.

As shown in FIG. 3, the magneto-resistive element MTJ has a memory layer 31, a tunnel barrier layer 32, a reference layer 33 and so on.

The memory layer 31 is formed on a lower electrode 27, through a foundation layer which is not shown here. The memory layer 31 is a ferromagnetic layer with variable magnetization directions, and has a perpendicular or near-perpendicular magnetization to the film surface (upper surface/lower surface). The memory layer 31 has a perpendicular or near-perpendicular magnetization to the film surface at the interface with a tunnel barrier layer 32, which will be discussed later. Here, variable magnetization directions mean that the magnetization direction changes corresponding to a given writing current. Also, “near perpendicular” means that the direction of the residual magnetization to the film surface is within 45°<θ≦90°.

Also, the memory layer 31 is composed of ferromagnetics, including, for example, Co and Fe. Also, B is added to the ferromagnetics for the purpose of adjusting the saturation magnetization, crystal orientation and so on. Here, such elements as C and Si can be added to the ferromagnetics. Also, the thickness of the memory layer 31 is about 0.7 nm or more but less than 1.2 nm, but its thickness is adjusted corresponding to the Fe composition ratio. Details of a sample execution for the thickness and the Fe composition ratio of the memory layer 31 of this embodiment will be discussed later.

The tunnel barrier layer 32 is formed on the memory layer 31. The tunnel barrier layer 32 is a non-magnetic layer, and composed of, for example, MgO.

A reference layer 33 is formed over the tunnel barrier 32. The reference layer 33 is a ferromagnetic layer with a fixed magnetization direction, and has a perpendicular or near perpendicular magnetization to the film surface. Here, the fixed magnetization direction means that the magnetization direction does not change corresponding to a given writing current. In other words, the reference layer 33 has a larger inverse energy barrier than the memory layer 31.

Also, the reference layer 33, for example, is composed of ferromagnetics, which includes more than one element among Co, Fe, B, Ni, Ir, Pt, Mn, or Ru. The reference layer 33 is composed of, for example, Co_{1-Y}Fe_{Y}B (0<Y<1, for example Y=0.9).

A hard mask 34 is formed on the reference layer 33. The hard mask 34 is composed of a metallic material that bears conductivity. For example, it is composed of TiN. Also, it is not limited thereto; it can be composed of a film that includes Ti, Ta, or W, or a layered film with these elements.

An upper electrode 28 is formed on the hard mask 34. The upper electrode 28 and the magneto-resistive element MTJ are electrically connected through the hard mask 34 by forming the hard mask 34, which is composed of a metallic material, in such a way as it contacts the upper electrode 28.

A planer shape of the memory layer 31, the tunnel barrier 32, the reference layer 33, and the hard mask 34 is, for example, circular. For this reason, the magneto-resistive element MTJ is formed in a pillar shape.

Here, even though it is not shown in the drawing, an interface layer can be formed between the reference layer 33 and the tunnel barrier 32. The interface layer ensures lattice consistency with the tunnel barrier layer 32, which it contacts at the bottom. The interface layer, for example, is composed of the same materials as the reference layer 33, but its composition ratio can be different.

Also, a shift adjusting layer can be formed on the reference layer 33, through a spacer layer (for example, Ru, etc.), which is not shown in the drawings. The shift adjusting layer is a magnetic layer with a fixed magnetization direction, and has a perpendicular or near perpendicular magnetization to the film surface. Also, its magnetization direction is opposite to that of the reference layer 33. Because of this, the shift adjusting layer can cancel out the leakage magnetic field applied to the memory layer 31 from the reference layer 33. In other words, the shift adjusting layer has an effect of adjusting the fringe magnetic field that is offset from the reference layer 33 to the memory layer 31 in the opposite direction. This shift adjusting layer is composed of, for example, an artificial lattice, which has a layered structure of magnetic materials such as Ni, Fe, Co and so on, and non-magnetic material such as Cu, Pd, Pt and so on.

Also, the memory layer 31 and the reference layer 33 can have different planar sizes. For example, the diameter of the memory layer 31 can be bigger than the diameter of reference layer 33. By this, an electric short between the memory layer 31 and the reference layer 33 can be prevented. Here, the planer shape of the magneto-resistive element MTJ is not limited to be circular, but can be in a shape such as square, rectangular, or oval.

Also, the memory layer 31 and the reference layer 33 can be arranged in the reverse order. Namely, on the lower electrode 27, the reference layer 33, the tunnel barrier layer 32, and the memory layer 31 can be formed in this order.

### Operational Examples

Next, the operational examples of the magneto-resistive element MTJ will be explained.

The magneto-resistive element MTJ is, for example, a spin-injection type magneto-resistive element. Therefore, when data are written into the magneto-resistive element MTJ, or when data are readout of the magneto-resistive element MTJ, currents in both directions perpendicular to the film surface are applied to the magneto-resistive element MTJ.

The write operation to the magneto-resistive element MTJ is performed as follows.

When electrons are supplied from the side of the upper electrode 28 (electrons moving from the reference layer 33 to the memory layer 31), electrons, which underwent the spin-polarization in the same direction as the magnetization direction of the reference layer 33, are injected into the memory layer 31. In this case, the magnetization direction of the memory layer 31 is aligned in the same direction as the magnetization direction of the reference layer 33. By this, the magnetization directions of the reference layer 33 and the memory layer 31 are set in a parallel arrangement. In this parallel arrangement, the resistance value of the magneto-resistive element MTJ is the smallest. This case is defined as, for example, data “0”.

On the other hand, when electrons are supplied from the side of the lower electrode 27 (electrons moving from the memory layer 31 to the reference layer 33), electrons, which are reflected by the reference layer 33, and therefore, underwent the spin-polarization in the opposite direction to the magnetization direction of the reference layer 33, are injected into the memory layer 31. In this case, the magnetization direction of the memory layer 31 is aligned in the opposite direction to the magnetization direction of the reference layer 33. By this, the magnetization directions of the reference layer 33 and the memory layer 31 are set in an antiparallel arrangement. In this antiparallel arrangement, the resistance value of the magneto-resistive element MTJ is the largest. This case is defined as, for example, data “1”.

The read operation is performed as follows.

The reading current is supplied to the magneto-resistive element MTJ. This reading current is set to the value at which the magnetization direction of the memory layer 32 does not invert (a smaller value than that of the writing current). By detecting the change in the resistance value of the magneto-resistive element MTJ at this state, it becomes a semiconductor device, capable of a memory operation.

### Embodiment

Next, Examples 1 through 3 regarding the film thickness and Fe composition ratio of the memory layer 31 of this embodiment will be explained.

In Example 1, the memory layer 31 is composed of Co₁₋ₓFeₓB (0.4≦x<0.6, for example, x=0.5). In addition, the thickness of the memory layer 31 is adjusted to be 0.7 nm or more but less than 1 nm.

In Example 2, the memory layer 31 is composed of Co₁₋ₓFeₓB (0.6≦x<0.8, for example x=0.7). In addition, the thickness of memory 31 is adjusted to be 0.7 nm or more but less than 1.1 nm.

In Example 3, the memory layer 31 is composed of Co₁₋ₓFeₓB (0.8≦x<1.0, for example, x=0.9). In addition, the thickness of the memory 31 is adjusted to be 0.7 nm or more but less than 1.2 nm.

The upper limits of the thickness of the memory layer in Examples 1 through 3 are determined so that the perpendicular anisotropic magnetic field in the memory layer 31 does not become 0. On the other hand, the lower limits of the thickness of the memory layer 31 in Examples 1 through 3 are determined so that it has enough MR (Magneto Resistivity) ratios, and the limitation of the deposition technology is also taken into consideration. Details will be discusses later, but the thickness is kept within the range in which ΔE can be kept constant.

By setting the thickness and Fe composition ratio of the memory layer 31 to be within the ranges determined above, it becomes possible to reduce the inverse current Ic while keeping the inverse energy barrier ΔE high. Also, it is desirable that the thickness of the memory layer 31 be set as large as possible within the above ranges. By this, it becomes possible to reduce the inverse current Ic even further while keeping the inverse energy barrier ΔE high.

The basis for the thickness and Fe composition ratio of the memory layer 31 in Examples 1 through 3 will be discussed later.

### (Basis for the Thickness and Fe Composition Ratio of the Memory Layer)

Next, the basis for the thickness of film and Fe composition ratio of the memory layer 31 of this embodiment will be explained using FIG. 4 through FIG. 8.

In MRAM, the inverse current Ic and the inverse energy barrier ΔE are expressed in the following Equations (1) and (2).

$$\begin{matrix}( Equation 1 ) & \\ {I}_{C} ∝ \frac{2 e}{h} \cdot \frac{α Ms}{g ( θ )} {Hk}_{eff} & ( 1 ) \\ ( Equation 2 ) & \\ Δ E = \frac{{Hk}_{eff} Ms V}{2 kT} & ( 2 )\end{matrix}$$

Here, e denotes the elementary electric charge, a denotes friction coefficient, Ms denotes saturating magnetization, h-bar denotes a constant obtained by dividing Planck's constant by 2π, g(θ) denotes a spin injection efficiency, V denotes the volume of the memory layer 31, k denotes Boltzmann's factor, T denotes the temperature, and Hk_{eff} denotes the anisotropic magnetic field.

As shown in Equations (1) and (2), both inverse current Ic and inverse energy barrier ΔE depend on Hk_{eff}. Therefore, by adjusting Hk_{eff}, it is possible to control inverse current Ic and inverse energy barrier ΔE.

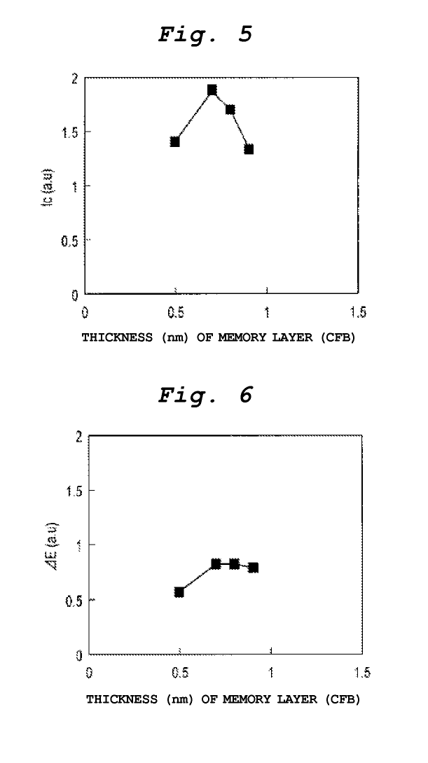

FIG. 4 through FIG. 7 show the experimental results of each parameter regarding the thickness of the memory layer 31. More specifically, FIG. 4 is a graph showing the relationship between the thickness of the memory layer 31, and Hk (Hk_{eff}) and Hc. FIG. 5 is a graph showing the relationship between the thickness of the memory layer 31 and Ic. FIG. 6 is a graph showing the relationship between the thickness of the memory layer 31 and ΔE. FIG. 7 is a graph showing the relationship between the thickness of the memory layer 31 and Ic/ΔE. All of the graphs show the case in which memory layer 31 is composed Co₁₋ₓFeₓB (x=0.5).

In these graphs, Hc, as well as Hk, shows the magnetic parameter for the magnetization inversion, and is coercive. To be more concrete, Hc is a magnetic parameter for the magnetization inversion measured by an element unit at the memory layer 31, and Hk is a magnetic parameter for the magnetization inversion, which is measured by a film unit before it is broken into elements at the memory layer 31. Ideally, when a magnetization inversion occurs in a single magnetic domain, Hc equals Hk. In this embodiment, the memory layer 31 has the perpendicular anisotropy at the interface with the tunnel barrier 32, and ΔE and Ic are determined by the perpendicular anisotropy (Hk) at this interface.

As shown in FIG. 4, when the thickness of the memory layer 31 is between 0.5 nm and 0.7 nm, Hc and Hk become high. The reasons for that are as follows. The memory layer 31 has insufficient film forming condition when the thickness is about 0.5 nm. Therefore, such properties as the MR ratio and so on are also inferior. By increasing the thickness of the memory layer 31 to about 0.7 nm, sufficient film forming condition is achieved, and such properties as the MR ratio also improve. As a result, the magnetic parameters for the magnetization inversion (Hk, Hc) of the memory layer 31 become greater at the interface with the tunnel barrier layer 32. Therefore, when the thickness of the memory layer 31 is between 0.5 nm and 0.7 nm, the magnetization inversion becomes hard to occur at the memory layer 31.

On the other hand, when the thickness of the memory layer 31 is 0.7 nm or more, Hk and Hc become small. The reasons for that are as follows. Even if the thickness of the memory layer 31 becomes greater than 0.7 nm, the value of the perpendicular anisotropic magnetic field itself does not change. However, when the thickness of the memory layer 31 is 0.7 nm or more, at the memory layer 31, the contribution made by the original in-plane anisotropy of the materials (CoFeB) other than the interface with the tunnel barrier 32 becomes greater. By this, the perpendicular anisotropy at the interface and the original in-plane anisotropy of the materials other than the interface cancel out. As a result, when the thickness of the memory layer 31 becomes greater than 0.7 nm, the magnetic parameter of the magnetization inversion of the memory layer 31 (Hk, Hc) becomes small, making it easy for the magnetization inversion to occur.

When the thickness of the memory layer 31 is increased to be about 1 nm, the magnetic parameters for the magnetization inversion (Hk, Hc) become 0.

As shown in FIG. 5, Ic depends on Hc and Hk. Therefore, when the thickness of the memory layer 31 is between 0.5 nm and 0.7 nm, Ic becomes large. When the thickness of the memory layer 31 is more than 0.7 nm, Ic becomes small. This is because, as shown in the above Equation 1, Ic and Hk have a proportional relationship. Also, even though it is not shown in the drawing, when the thickness of the memory layer 31 is increased to about 1 nm, Ic becomes 0.

As shown in FIG. 6, when the thickness of the memory layer 31 is between 0.5 nm and 0.7 nm, ΔE becomes large. This is because, as shown in the above Equation 2, ΔE depends on Hk.

On the other hand, even if the thickness of the memory layer 31 is 0.7 nm or more, ΔE does not change. More precisely, when the thickness of the memory layer 31 is 0.7 nm or greater but less than 1.0 nm, ΔE is constant. The reasons are as follows. As mentioned above, the thickness is 0.7 nm or greater, Hk becomes small. However, the volume of the memory layer 31 V becomes large. As shown in the above Equation 2, ΔE has a proportional connection to Hk and V. When the thickness of the memory layer 31 is 0.7 nm or greater but less than 1.0 nm, the decrease in Hk and increase in V cancel out. As a result, ΔE becomes constant.

Also, even though it is not shown in the drawing, when the thickness of the memory layer 31 is increased to be about 1 nm, ΔE becomes 0.

As can be seen from FIG. 5, FIG. 6, and FIG. 7, when the thickness of the memory layer 31 increases, Ic/ΔE decreases. Therefore, Ic becomes smaller for ΔE. In this embodiment, in order to reduce the writing current while suppressing the deterioration of the data retention property, it is necessary to keep the inverse current Ic small while keeping the inversion energy barrier ΔE constant. For this reason, the thickness of the memory layer 31 is set to be in the range of 0.7 nm or more but less than 1.0 nm, in which ΔE is kept constant. Furthermore, in order to keep Ic small, it is desirable to set the film of the memory layer 31 as thick as possible within the range in which Hk does not become 0.

In this way, when the memory layer 31 is composed of Co₁₋ₓFeₓB (x=0.5), the above effect can be obtained by setting the film of the memory layer 31 as thick as possible within the range of 0.7 nm or more but less than 1.0 nm.

FIG. 4 through FIG. 7 discussed the case in which the memory layer 31 is composed of Co₁₋ₓFeₓB (x=0.5). The following discusses the cases in which the Fe composition ratio of the memory layer 31 is changed, or in other words, when the memory layer 31 is composed of Co₁₋ₓFeₓB (x=0.7 or 0.9).

FIG. 8 is a graph showing the relation between the thickness of the memory layer 31 and Hk as the Fe composition ratio of the memory layer 31 changes, and showing the calculation results.

As shown in FIG. 8, when the thickness of the memory layer 31 is 0.7 nm or more, as the Fe composition ratio of the memory layer 31 increases, the perpendicular anisotropy magnetic field (Hk) increases. By this, the thickness of the memory layer 31 at which Hk is 0 becomes greater. Therefore, the upper limit of the thickness of the memory layer 31 can be made greater. More specifically, when the memory layer 31 is composed of Co₁₋ₓFeₓB (x=0.7), if the thickness of the memory layer 31 is increased to about 1.1 nm, Hk becomes 0. Also, when the memory layer 31 is composed of Co₁₋ₓFeₓB (x=0.9), if the thickness of the memory layer 31 is increased to about 1.2 nm, Hk becomes 0.

On the other hand, even if the Fe composition ratio of the memory layer 31 is increased, such factors as the film forming condition and MR ratio properties do not change. Therefore, the lower limit of the thickness of the memory layer 31 does not change and remain at about 0.7 nm.

For this reason, when the memory layer 31 is composed of Co₁₋ₓFeₓB (x=0.7), ΔE is kept constant within the range in which the thickness of the memory layer 31 is 0.7 nm or more but less than 1.1 nm. Also, when the memory layer 31 is composed of Co₁₋ₓFeₓB (x=0.9), ΔE is kept constant within the range in which the thickness of the memory layer 31 is 0.7 nm or more but less than 1.2 nm.

In this way, when the memory layer 31 is composed of Co₁₋ₓFeₓB (x=0.7), the above effect can be achieved by setting the film of the memory layer 31 as thick as possible within the range of 0.7 nm or more but less than 1.1 nm. Also, when the memory layer 31 is composed of Co₁₋ₓFeₓB (x=0.9), the above effect can be achieved by setting the film or the memory layer 31 as thick as possible within the range of 0.7 nm or more but less than 1.2 nm.

### (Effects)

According to the above embodiment, adjustments are made to the thickness and Fe composition ratio of the memory layer 31 of the magneto-resistive element MTJ. When the memory layer 31 is composed of Co₁₋ₓFeₓB (0.4≦x<0.6, for example, x=0.5), the thickness of the memory layer 31 is adjusted to 0.7 nm or greater but less than 1 nm. When the memory layer 31 is composed of Co₁₋ₓFeₓB (0.6≦x<0.8, for example, x=0.7), the thickness of the memory layer 31 is adjusted to 0.7 nm or more but less than 1.1 nm. When the memory layer 31 is composed of Co₁₋ₓFeₓB (0.8≦x<1.0, for example, x=0.9), the thickness of the memory layer 31 is adjusted to 0.7 nm or more but less than 1 nm. In this way, by adjusting the thickness and Fe composition ratio of the memory layer 31, the inverse current Ic is made small while the inverse energy barrier ΔE is kept large. By this, it is possible to reduce the writing current while suppressing the deterioration of the data retention properties.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magneto-resistive element, comprising:
first and second layers each having magnetic anisotropy along a direction perpendicular to a surface thereof, the first layer having a variable magnetization direction and the second layer having a fixed magnetization direction; and
a tunnel barrier layer between the first layer and the second layer,
wherein the first layer is composed of Co₁₋ₓFeₓB (0.4≦x<0.6), and has a thickness of 0.7 nm or more but less than 1.0 nm.

2. The magneto-resistive element of claim 1, wherein an inverse energy barrier of the first layer is smaller than an inverse energy barrier of the second layer.

3. The magneto-resistive element of claim 1, wherein planar sizes of the first and second layers are different.

4. The magneto-resistive element of claim 1, wherein the second layer is a ferromagnetic layer.

5. The magneto-resistive element of claim 1, wherein the magnetization direction of the first layer changes and the magnetization direction of the third layer does not change when a write current is injected across the first layer, the tunnel barrier layer, and the second layer.

6. The magneto-resistive element of claim 1, wherein the first layer has the magnetic anisotropy perpendicular to a surface of the first layer at an interface between the first layer and the tunnel barrier layer.

7. The magneto-resistive element of claim 1, wherein the tunnel barrier layer is composed of MgO, and the reference layer is composed of Co_{1-Y}Fe_{Y}B (where 0<Y<1).

8. A magneto-resistive element, comprising:
first and second layers each having magnetic anisotropy along a direction perpendicular to a surface thereof, the first layer having a variable magnetization direction and the second layer having a fixed magnetization direction; and
a tunnel barrier layer between the first layer and the second layer,
wherein the first layer is composed of Co₁₋ₓFeₓB (0.6≦x<0.8), and has a thickness of 0.7 nm or more but less than 1.1 nm.

9. The magneto-resistive element of claim 8, wherein an inverse energy barrier of the first layer is smaller than an inverse energy barrier of the second layer.

10. The magneto-resistive element of claim 8, wherein planar sizes of the first and second layers are different.

11. The magneto-resistive element of claim 8, wherein the second layer is a ferromagnetic layer.

12. The magneto-resistive element of claim 8, wherein the magnetization direction of the first layer changes and the magnetization direction of the third layer does not change when a write current is injected across the first layer, the tunnel barrier layer, and the second layer.

13. The magneto-resistive element of claim 8, wherein the first layer has the magnetic anisotropy perpendicular to a surface of the first layer at an interface between the first layer and the tunnel barrier layer.

14. The magneto-resistive element of claim 8, wherein the tunnel barrier layer is composed of MgO, and the reference layer is composed of Co_{1-Y}Fe_{Y}B (where 0<Y<1).

15. A magneto-resistive element, comprising:
first and second layers each having magnetic anisotropy along a direction perpendicular to a surface thereof, the first layer having a variable magnetization direction and the second layer having a fixed magnetization direction; and
a tunnel barrier layer between the first layer and the second layer,
wherein the first layer is composed of Co₁₋ₓFeₓB (0.8≦x<1.0), and has a thickness of 0.9 nm or more but less than 1.2 nm.

16. The magneto-resistive element of claim 15, wherein an inverse energy barrier of the first layer is smaller than an inverse energy barrier of the second layer.

17. The magneto-resistive element of claim 15, wherein planar sizes of the first and second layers are different.

18. The magneto-resistive element of claim 15, wherein the magnetization direction of the first layer changes and the magnetization direction of the third layer does not change when a write current is injected across the first layer, the tunnel barrier layer, and the second layer.

19. The magneto-resistive element of claim 15, wherein the first layer has the magnetic anisotropy perpendicular to a surface of the first layer at an interface between the first layer and the tunnel barrier layer.

20. The magneto-resistive element of claim 15, wherein the tunnel barrier layer is composed of MgO, and the reference layer is composed of Co_{1-Y}Fe_{Y}B (where 0<Y<1).
